(19) United States
(12) Patent Application Publication
(10) Pub. No.: US 2006/0177745 A1
(43) Pub. Date: Aug. 10, 2006

(54) Phase shift masks

(75) Inventors: Sung-min Huh, Gyeonggi-do (KR); Hee-bom Kim, Gyeonggi-do (KR); Seong-woon Choi, Gyeonggi-do (KR); Jin-hong Park, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/338,542

(22) Filed: Jan. 24, 2006

(30) Foreign Application Priority Data
Feb. 5, 2005 (KR) 10-2005-0011012

(51) Int. Cl. G03C 5/00; G03F 1/00

(52) U.S. Cl. 430/5; 430/322; 430/323

(57) ABSTRACT

A phase shift mask (PSM) is provided. The PSM includes a light-transmitting substrate, a light-blocking region, a first light-transmitting region, and a second light-transmitting region. The light-blocking region is formed in the light-transmitting substrate. The first light-transmitting region is formed as both a first phase shift region for transmitting 0°-phase shifted light and as a first polarization region for TE-polarizing the transmitted light. The second light-transmitting region contacts the first light-transmitting region to form a boundary. The second light-transmitting region is formed in the light-transmitting substrate as a second phase shift region for transmitting 180°-phase shifted light and as a second polarization region for TM-polarizing the transmitted light to prevent a phase conflict at the boundary.

### CROSS-REFERENCE TO RELATED PATENT APPLICATION

This application claims the benefit of priority from Korean Patent Application No. 10-2005-0011012, filed on Feb. 5, 2005, in the Korean Intellectual Property Office, the disclosure of which is incorporated herein in its entirety by reference.

### FIELD OF THE INVENTION

The present invention relates to the manufacture of semiconductor devices, and more particularly, to photolithography using a phase shift mask (PSM).

### BACKGROUND OF THE INVENTION

As the design rule of semiconductor devices is reduced, technology for forming a pattern having a line width less than a resolution limit in photolithography equipment is required. Accordingly, technology for forming a fine pattern using a PSM is used. For example, technology using a double exposure phase-edge PSM (double exposure PEPSM) has been introduced.

The double exposure PEPSM technology is expected to be useful for reducing the size of a gate of a transistor, and, thus, is drawing attention as a technology that can be used to realize a reduction of the gate line width, which is required for a next-generation or next-next generation device using exposure equipment of the present generation. Therefore, the double exposure PEPSM technology is drawing attention as a technology capable of producing high performance transistors with high resolution.

To apply such technology, a phase conflict between phase shifters or phase shift regions that are out of phase and adjacent to each other should be prevented. If the phase conflict occurs, an undesired pattern or line is transferred onto a wafer.

FIG. 1 is a schematic plan view of a conventional prior art PSM. FIG. 2 is a schematic view of a wafer image obtained when exposure is performed using the PSM of FIG. 1.

Referring to FIG. 1, a typical PEPSM structure is manufactured by forming light-blocking patterns 21 and 25 on a light-transmitting substrate 10 (such as a quartz substrate) and introducing first phase shift regions 31 and 33 and second phase shift regions 41 and 43 so that light of different phases may be provided on opposite sides of the light-blocking patterns 21 and 25. For example, the first phase shift regions 31 and 33 and the second phase shift regions 41 and 43 may be formed so that light passing through the regions have a phase difference of 180°. The phase difference can be realized by etching a portion of the light-transmitting substrate 10 that corresponds to one of the phase shift regions to a predetermined depth.

However, if light exposure is performed using the mask shown in FIG. 1, an undesired pattern image 50 can be generated on a portion of the wafer corresponding to the light-blocking patterns 21 and 25 as illustrated in FIG. 2. The undesired pattern image 50 is substantially generated due to a phase difference between the first phase shift region 33 and the second phase shift region 41, which are adjacent to each other.

As illustrated in FIG. 1, when the linear or line-shaped first light-blocking pattern 21 and the linear or line-shaped second light-blocking pattern 25 are perpendicular to each other, the first phase shift region 31 and the second phase shift region 41 are disposed on opposite sides of the first light-blocking pattern 21 and the first phase shift region 33 and the second phase shift region 43 are disposed on opposite sides of the second light-blocking pattern 25 such that the first phase shift region 33 is adjacent to the first light-blocking pattern 21. Accordingly, a region where the second phase shift region 41 and the first phase shift region 33 are adjacent to each other is formed.

Because light passing through the second phase shift region 41 and light passing through the first phase shift region 33 at the contacting boundary have a phase difference of 180°, the light passing through the second phase shift region 41 and the light passing through the first phase shift region 33 destructively interfere with each other at the boundary. That is, a phase conflict is generated between the light having a phase of 0° and the light having a phase of 180°. Accordingly, because the intensity of light at the boundary actually delivered to the wafer becomes substantially zero due to the destructive interference, the undesired pattern image 50 is transferred as if a separate light-blocking pattern exists.

To remove or trim the undesired pattern 50, additional light-exposure using a separate trim mask is required. That is, double exposure is required. Accordingly, because the exposure should be performed sequentially using two masks, an exposure time is increased and process stability may deteriorate.

### SUMMARY OF THE INVENTION

Embodiments of the present invention provide a phase shift mask (PSM) capable of preventing a defect due to phase conflict effect (phase interference) when used in photolithography.

According to embodiments of the present invention, a phase shift mask (PSM) includes a light-transmitting substrate. A light-blocking region is disposed on the light-transmitting substrate. A first light-transmitting region is formed in the light-transmitting substrate and serves as a first phase shift region that phase-shifts a transmitted light by a first amount and as a first polarization region that first-polarizes the transmitted light to produce a first polarized light. A second light-transmitting region is formed in the light-transmitting substrate, contacts the first light-transmitting region, serves as a second phase shift region that phase-shifts a transmitted light by a second amount different from the first amount, and serves as a second polarization region that second-polarizes the transmitted light to produce a second polarized light with a polarization different from that of the first-polarized light.

The first polarization may be transverse electric (TE) polarization and the second polarization may be transverse magnetic (TM) polarization.

According to some embodiments, the first light-transmitting region includes a first grating extending in a predetermined direction and having a first depth to produce the first polarization, and the second light-transmitting region includes a second grating having a second depth greater than the first depth that results in a phase difference between the light transmitted through the first light-transmitting region and the light transmitted through the second light-transmitting region, the second grating extending in a direction perpendicular to the direction of the first grating to obtain a polarization different from the polarization produced by the first grating.

The pitch of the first grating or the second grating may be equal to the wavelength of the transmitted light.

The first depth may be a depth in a range where TE polarization prevails (e.g., according to some embodiments, about 0.1 μm).

The first light-transmitting region may be disposed on a first side of the light-blocking region and further include a third light-transmitting region that is formed in the light-transmitting substrate on a second side of the light-blocking region opposite to the first light-transmitting region and transmits light with a phase different from that of the light transmitted through the first phase shift region.

The third light-transmitting region may have a depth equal to the second depth and include a third grating extending in the same direction as the first grating.

According to some embodiments of the present invention, a phase shift mask (PSM) includes a light-transmitting substrate. A line-shaped light-blocking region is formed on the light-transmitting substrate. A first light-transmitting region is formed in the light-transmitting substrate on a first side of the light-blocking region, acts as a first phase shift region that phase-shifts a transmitted light by a first amount and acts as a first polarization region that first-polarizes the transmitted light to produce a first polarized light. A second light-transmitting region is formed in the light-transmitting substrate on a second side of the light-blocking region opposite to the first phase shift region, acts as a second phase shift region that phase-shifts a transmitted light by a second amount different from the first amount, and acts as another first polarization region that first-polarizes the transmitted light to produce a further first polarized light. A third light-transmitting region is formed in the light-transmitting substrate, contacts the first and second light-transmitting regions to form a boundary at an end of the light-blocking region, and acts as another first phase shift region and a second polarization region that second-polarizes the transmitted light to produce a second polarized light.

According to further embodiments of the present invention, a phase shift mask (PSM) includes a light-transmitting substrate. A light-blocking region is formed on the light-transmitting substrate. A first phase shift region is formed in the light-transmitting substrate and transmits light with a first phase. A second phase shift region is formed in the light-transmitting substrate, contacts the first phase shift region to form a boundary, and transmits light with a second phase different from the first phase. A first polarization part is formed in the first phase shift region adjacent to the boundary to first-polarize the transmitted light. A second polarization part is formed in the second phase shift region adjacent to the boundary to second-polarize the transmitted light.

Further features, advantages and details of the present invention will be appreciated by those of ordinary skill in the art from a reading of the figures and the detailed description of the preferred embodiments that follow, such description being merely illustrative of the present invention.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic plan view of a conventional prior art phase shift mask (PSM);

FIG. 2 is a schematic view of a wafer image obtained when an exposing process is performed using the PSM of FIG. 1;

FIGS. 3A through 3C are schematic views of a PSM according to embodiments of the present invention and its operation;

FIG. 4 is a schematic view illustrating the results of a simulation of a TE polarization ratio with respect to a pitch and a depth of a polarization grating; and

FIG. 5 is a schematic view illustrating the results of a simulation used to determine transmittance with respect to a pitch and a depth of a polarization grating.

### DETAILED DESCRIPTION OF EMBODIMENTS OF THE INVENTION

The present invention now will be described more fully hereinafter with reference to the accompanying drawings, in which illustrative embodiments of the invention are shown. In the drawings, the relative sizes of regions or features may be exaggerated for clarity. This invention may, however, be embodied in many different forms and should not be construed as limited to the embodiments set forth herein; rather, these embodiments are provided so that this disclosure will be thorough and complete, and will fully convey the scope of the invention to those skilled in the art.

It will be understood that when an element is referred to as being “coupled” or “connected” to another element, it can be directly coupled or connected to the other element or intervening elements may also be present. In contrast, when an element is referred to as being “directly coupled” or “directly connected” to another element, there are no intervening elements present. Like numbers refer to like elements throughout.

In addition, spatially relative terms, such as “under”, “below”, “lower”, “over”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly.

Well-known functions or constructions may not be described in detail for brevity and/or clarity.

As used herein the expression “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In a phase shift mask (PSM) according to embodiments of the present invention, a first polarization region, which is a 180° phase shift region, polarizes transmitted light into a transverse electric (TE) mode and a second polarization region, which is a 0° phase shift region, polarizes the transmitted light into a transverse magnetic (TM) mode in order to prevent a phase conflict from occurring at a boundary between the 0° and 180° phase shift regions. Because interference due to a phase difference does not occur between light polarized into TE and TM modes, a phase conflict does not occur.

Therefore, additional exposure using a separate trim mask for removing an undesired pattern (i.e., a trim pattern generated due to a phase conflict) can be omitted. That is, it is possible to form a fine pattern using only a single light exposure using only the PSM. Particularly, it is possible to form a fine pattern in the shape of a line or a space (e.g., a gate pattern of a transistor) with a pattern line width smaller than the wavelength of an exposure light source used for the exposure. Therefore, it is possible to overcome a resolution limit of conventional exposure equipment and form a finer pattern.

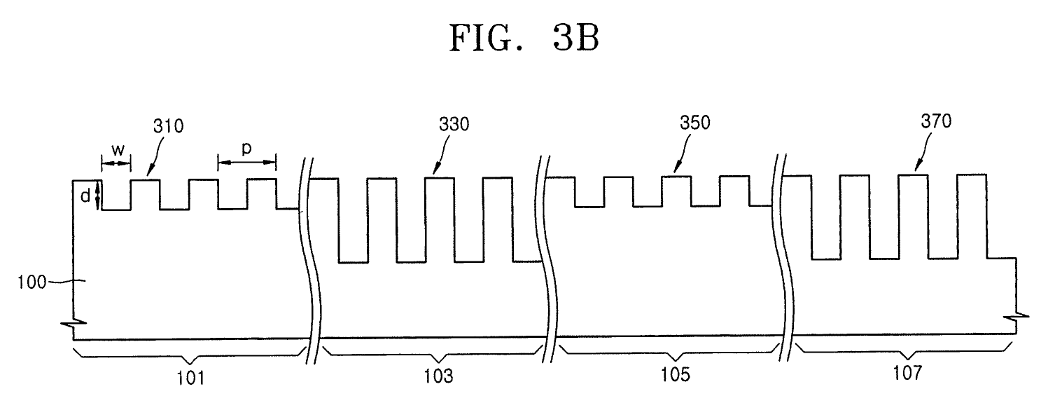

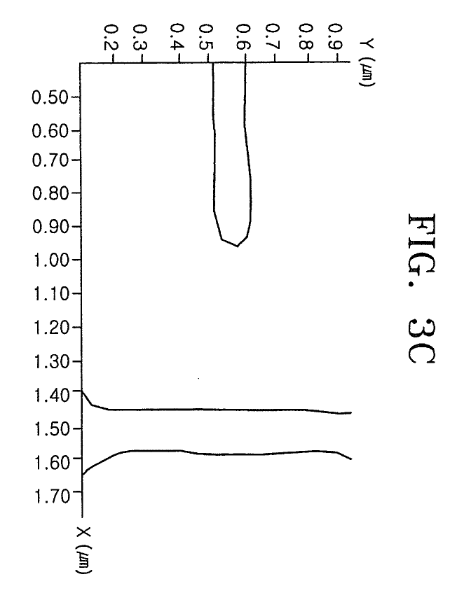

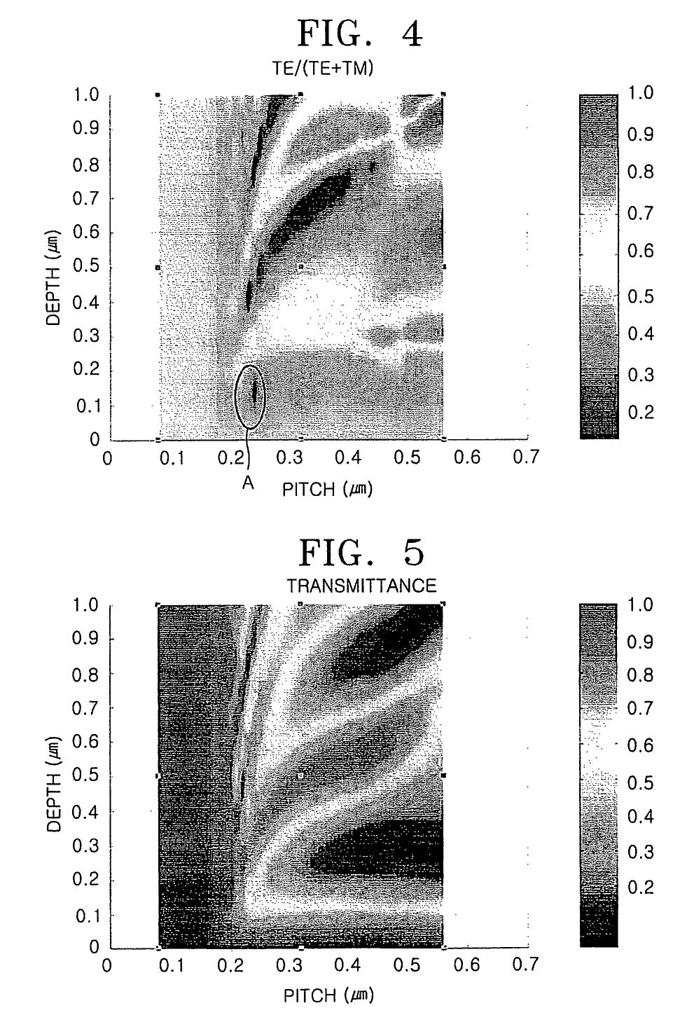

FIGS. 3A through 3C are schematic views of a PSM according to embodiments of the present invention and its operation. FIG. 4 is a schematic view illustrating a TE polarization ratio with respect to a pitch and a depth of a polarization grating. FIG. 5 is a schematic view illustrating a transmittance with respect to a pitch and a depth of a polarization grating.

Referring to FIG. 3A, the PSM according to embodiments of the present invention includes light-blocking regions 210 and 250 formed by forming and patterning a light-blocking layer on a light-transmitting substrate 100. To realize optical interference through a phase difference (e.g., a phase difference of 180°) in the light-blocking regions 210 and 250, first phase shift regions 101, 105 and second phase shift regions 103, 107 having an optical phase difference are formed in opposite sides of the light-blocking regions 210 and 250.

In this configuration, it is possible to realize an optical phase difference of 180° so that the first phase shift regions 101 and 105 and the second phase shift regions 103 and 107 interfere (more particularly, interfere destructively). For example, the first phase shift regions 101 and 105 and the second phase shift regions 103 and 107 may be given a phase difference by varying their depths when etching the light-transmitting substrate 100 (e.g., a quartz substrate). That is, the first phase shift regions 101 and 105 can constitute a region of the light-transmitting substrate 100 with the same height as the light-transmitting substrate 100 and the second phase shift regions 103 and 107 can constitute a region of the light-transmitting substrate 100 etched to a predetermined depth.

The depth to which the second phase shift regions 103 and 107 are etched can be set according to the wavelength of the exposure light source used for the exposure and according to a phase difference to be realized. When the first phase shift regions 101 and 105 have the same height as the light-transmitting substrate 100 so that transmitted light has a phase of 0° and the second phase shift regions 103 and 107 are set so that transmitted light has a phase difference of 180° with respect to light transmitted through the first phase shift regions 101 and 105, the second phase shift regions 103 and 107 can be etched to a depth of about 2400 Å in the case where the exposure light source is KrF having a wavelength of 248 nm. Also, the second phase shift regions 103 and 107 can be etched to a depth of about 1720 Å in the case where the exposure light source is ArF having a wavelength of 193 nm.

When the light-blocking regions 210 and 250 have a linear or line-shaped pattern such as a gate pattern of a transistor, the direction in which the first light-blocking region 210 extends and the direction in which the second light-blocking region 250 extends can be different. For example, the directions in which the first light-blocking region 210 and the second light-blocking region 250 extend can be perpendicular to each other. Accordingly, a boundary between the second phase shift region 103 and the first phase shift region 105 is clearly formed.

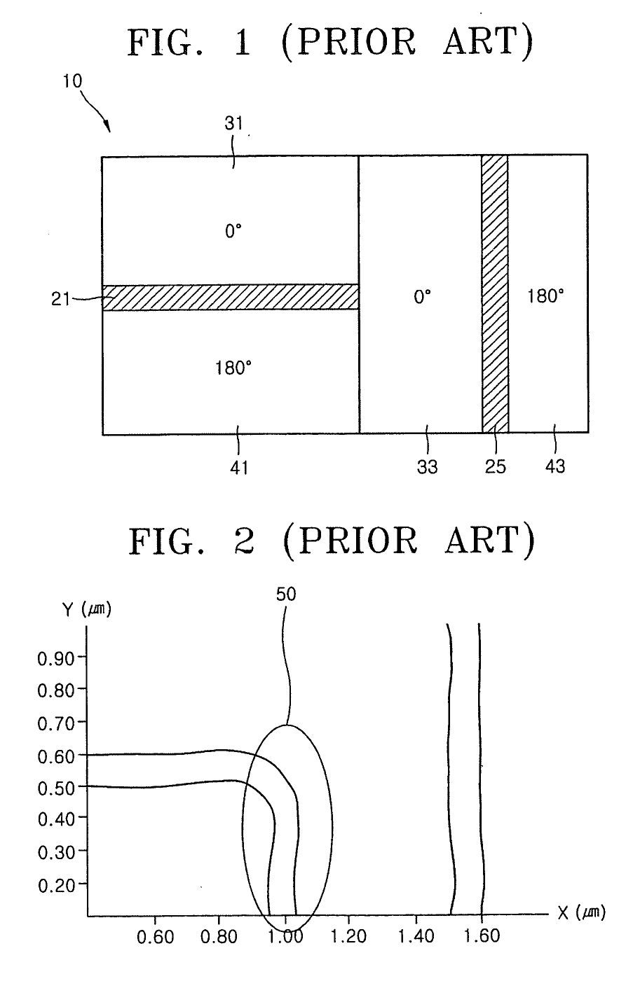

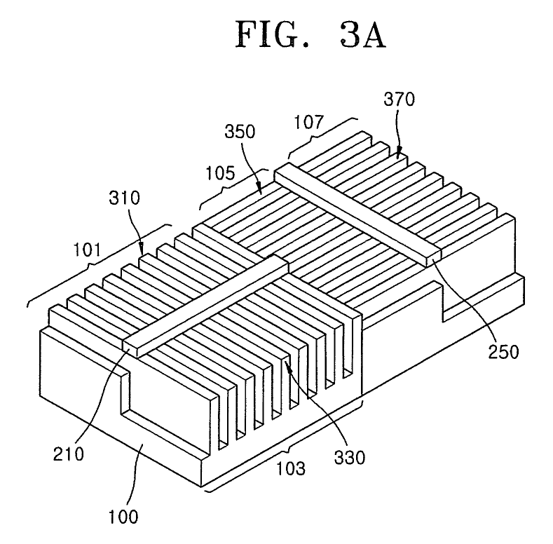

The phase conflict as described with reference to FIGS. 1 and 2 can occur at such a boundary due to a phase difference (i.e., a phase difference of 180°) between light transmitted through the second phase shift region 103 and the first phase shift region 105, even if the light-blocking pattern does not exist at the boundary. Accordingly, an undesired pattern image (e.g., pattern image 50 in FIG. 2) is transferred onto the wafer and an undesired pattern (i.e., a trim pattern) can be formed on the wafer.

To prevent the undesired phase conflict, embodiments of the present invention make use of a phenomenon that TE polarized light and TM polarized light do not interfere with one another even if they have a phase difference of 180°. To generate the TE polarized light and the TM polarized light, a second polarization part is formed on the first phase shift region 105 to perform first-polarization (e.g., TM-polarization) on transmitted light and a second polarization part is formed on the second phase shift region 103 adjacent to a boundary to perform second-polarization (e.g., TE-polarization) on transmitted light.

The first and second polarization parts polarize light to have a TE mode and a TM mode, respectively. The first and second polarization parts can be formed using various shapes (e.g., an additional polarization film). A grating shape can be adopted for the first and second polarization parts. The grating can include grooves formed by etching the light-transmitting substrate 100 to a predetermined depth. The grooves can extend in a predetermined direction to form a grating direction. The directions of the gratings formed in the first and second polarization parts are perpendicular to each other, so that one grating can generate TE polarized light and the other grating can generate TM polarized light.

A degree of a polarization can be controlled according to the size of the grating pattern, the pitch of the grating pattern including the grooves and protrusions, and the etched depth of the grooves. Thus, it is possible to set a depth, a pitch, and a size of a grating pattern in consideration of the pitch of the grating, transmittance of light at the pitch, and a degree of polarization.

When the first and second polarization parts are in the form of the grating formed by etching the light-transmitting substrate 100 as described above, the first phase shift regions 101, 105 and the second phase shift regions 103 or 107 can be as illustrated in FIGS. 3A and 3B.

Referring to FIGS. 3A and 3B, portions of the light-transmitting substrate 100 except the light-blocking regions 210 and 250 can be considered to be light-transmitting regions. The first phase shift region 101 disposed on one side of the first light-blocking region 210 can be considered to be a first light-transmitting region 101. The first light-transmitting region 101 can include a first grating 310 polarizing light having a phase of 0° to have a TE mode.

Also, the second phase shift region 103 disposed on the other side of the first light-blocking region 210 and generating a phase shift of 180°, thereby causing interference with the first phase shift region 101, can be considered to be a second light-transmitting region 103. The second light-transmitting region 103 can include a second grating 330 polarizing light having a phase of 180° to have a TE mode.

Likewise, the first phase shift region 105 disposed on one side of the second light-blocking region 250, separated from the first light-blocking region 210, and perpendicular to the first light-blocking region 210 can be considered to be a third light-transmitting region 105. The third light-transmitting region 105 can include a third grating 350 transmitting light having a phase of 0°, as in the first light-transmitting region 101, but being TM-polarized, unlike the first light-transmitting region 101.

Also, the second phase shift region 107 disposed on the other side of the light-transmitting substrate 100, opposite to the second light-blocking region 250 and generating a phase shift of 180°, thereby causing interference with the first phase shift region 105, can be considered to be a fourth light-transmitting region 107. The fourth light-transmitting region 107 can include a fourth grating 370 polarizing light having a phase of 180° to have a TM mode.

The first grating 310 functions as the first phase shift region that first-phase shifts (i.e., 0°-phase shifts) a light transmitted by the first light-transmitting region 101 and simultaneously functions as the first polarization part that first-polarizes (i.e., TE-polarizes) the light. Since the first phase shift region that 0°-phase shifts the light can be set to the surface region of the light-transmitting substrate 100, the first grating 310 can function as a grating polarizer for TE polarization.

The degree of TE polarization by the grating 310 can be determined according to factors such as the depth ‘d’, the size or the width ‘w’, and the pitch of the grating. The degree of TE polarization depending on the pitch ‘p’ and the depth ‘d’ of the grating used and estimated through simulation and the simulation results obtained are illustrated in FIG. 4. The simulation was performed using KrF as the exposure light source.

A region where the degree of TM polarization is large (i.e., TE/(TE+TM)≈0) can be found from the simulation results, and a depth or a pitch that corresponds to said region is obtained. The grating 310 where the TE polarization is large can be formed by rotating the grating wherein the TM polarization is large by 90°. It is advantageous if an etching process used to form the grating is minimally performed when the PSM is manufactured. Also, considering the results of a simulation used to determine transmittance with respect to the pitch and the depth of the grating illustrated in FIG. 5, it is revealed that high transmittance is advantageous. Therefore, linearity of a critical dimension (CD) and an etched depth of the substrate 100 may be considered simultaneously.

Therefore, according to some embodiments of the present invention, to minimize the etched depth ‘d’, the depth ‘d’ of the grating can be about 0.1-0.2 μm, which is a depth that corresponds to a region A in FIG. 4 where the TM polarization prevails. The pitch ‘p’ of the grating can be approximately equal to the wavelength of the exposure light source used. Of course, the grating can be etched to a greater depth by considering another region in FIG. 4 where the degree of the TM polarization is large, but a shallow depth allows the best light transmittance. The grating where the TE polarization is greatest can be realized by rotating such a grating by 90°.

Thus, the depth ‘d’ of the first grating may be set to about 0.1 μm. The pitch ‘p’ of the grating may be 248 nm for the exposure light source of KrF and 193 nm for ArF. In these cases, the condition for transmittance is satisfied, as illustrated in FIG. 5. The width ‘w’ of the groove can be set to half of the pitch in consideration of simplicity of the etching process used to form the grating.

The second grating 330 illustrated in FIGS. 3A and 3B functions as the second phase shift region that second-phase shifts (i.e., 180°-phase shifts) a light transmitted by the second light-transmitting region 103 and simultaneously functions as the first polarization part that first-polarizes (e.g., TE-polarizes) the light. The second phase shift region that 180°-phase shifts the light can be formed by etching the surface of the light-transmitting substrate 100 to a depth of about 2400 Å for the exposure light source composed of KrF or can be formed by etching the surface to a depth of about 1720 Å for the exposure light source composed of ArF.

Also, because the second grating 330 should include a grating polarization part for TE polarization, the second grating 330 can include a grating having a depth appropriate for generating a 180°-phase shift in light with respect to light transmitted through the first grating 310. Like the first grating 310, the second grating 330 can be formed to polarize light to have a TE mode. Thus, the second grating 330 can have the same grating direction as the first grating 310 and can be formed to a depth equal to the depth for the TE polarization plus a depth for the 180°-phase shift (e.g., at a depth of 0.34 μm obtained by adding a depth of about 0.24 μm for the 180°-phase shift in the case of the exposure light source composed of KrF to a depth of 0.1 μm for the TE polarization). Likewise, the second grating can be formed to a depth of about 0.27 μm for an exposure light source composed of ArF. The pitch of the second grating 330 may correspond to the wavelength of the exposure light source.

The third grating 350 illustrated in FIGS. 3A and 3B also functions as the first phase shift region that first-phase shifts (i.e., 0°-phase shifts) a light transmitted through the third light-transmitting region 105 and simultaneously functions as the second polarization part that second-polarizes (e.g., TM-polarizes) the light. Accordingly, when a grating producing TE mode polarization is rotated by 90°, the grating can be used for TM mode polarization, and thus the third grating 350 can be formed by rotating the first grating for the 0°-phase shift and TE mode polarization by 90°.

The fourth grating 370 illustrated in FIGS. 3A and 3B also functions as the second phase shift region that second-phase shifts (i.e., 180°-phase shifts) a light transmitted through the fourth light-transmitting region 107 and simultaneously functions as the second polarization part that second-polarizes (e.g., TM-polarizes) the light. Accordingly, when the grating producing TE mode polarization is rotated by 90°, the grating can be used for TM mode polarization, so the fourth grating 370 can be formed by rotating the second grating for the 180°-phase shift and TE mode polarization by 90°.

PSMs in accordance with embodiments of the present invention may serve to prevent the undesired trim pattern (reference numeral 50 in FIG. 1) from occurring due to interference which occurs conventionally, by introducing the polarization part polarizing light to have TE and TM modes (i.e., the gratings 330 and 350 at the boundary between the two phase shift regions 103 and 105 transmitting light with different phases). Therefore, a pattern transfer image similar to the first light-blocking pattern 210 and the second light-blocking pattern 250 can be realized as illustrated in FIG. 3C. Thus, it is possible to overcome the exposure limit of conventional exposure equipment and form a fine pattern using only single exposure using PSMs according to embodiments of the present invention without introducing a secondary exposure that requires an additional trim mask.

According to the embodiments of present invention, it is possible to prevent the phase interference from occurring by having adjacent regions where 0° and 180° phase shifting occurs produce TE and TM polarization, respectively. Thus, secondary exposure performed to remove the trim pattern using a trim mask can be omitted.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the invention.

What is claimed is:

1. A phase shift mask (PSM) comprising:
a light-transmitting substrate;
a light-blocking region disposed on the light-transmitting substrate;
a first light-transmitting region that is formed in the light-transmitting substrate and serves as a first phase shift region that phase-shifts a transmitted light by a first amount and as a first polarization region that first-polarizes the transmitted light to produce a first polarized light; and
a second light-transmitting region that is formed in the light-transmitting substrate, contacts the first light-transmitting region, serves as a second phase shift region that phase-shifts a transmitted light by a second amount different from the first amount, and serves as a second polarization region that second-polarizes the transmitted light to produce a second polarized light with a polarization different from that of the first-polarized light.

2. The PSM of claim 1, wherein the first polarization is transverse electric (TE) polarization and the second polarization is transverse magnetic (TM) polarization.

3. The PSM of claim 2, wherein the first light-transmitting region comprises a first grating extending in a predetermined direction and having a first depth to produce the first polarization, and the second light-transmitting region comprises a second grating having a second depth greater than the first depth that results in a phase difference between the light transmitted through the first light-transmitting region and the light transmitted through the second light-transmitting region, the second grating extending in a direction perpendicular to the direction of the first grating to obtain a polarization different from the polarization produced by the first grating.

4. The PSM of claim 3, wherein the pitch of the first grating or the second grating is equal to the wavelength of the transmitted light.

5. The PSM of claim 3, wherein the first depth is a depth in a range where TE polarization prevails.

6. The PSM of claim 3, wherein the first light-transmitting region is disposed on a first side of the light-blocking region and further comprises a third light-transmitting region that is formed in the light-transmitting substrate on a second side of the light-blocking region opposite to the first light-transmitting region and transmits light with a phase different from that of the light transmitted through the first phase shift region.

7. The PSM of claim 6, wherein the third light-transmitting region has a depth equal to the second depth and comprises a third grating extending in the same direction as the first grating.

8. A phase shift mask (PSM) comprising:
a light-transmitting substrate;
a line-shaped light-blocking region formed on the light-transmitting substrate;
a first light-transmitting region that is formed in the light-transmitting substrate on a first side of the light-blocking region, acts as a first phase shift region that phase-shifts a transmitted light by a first amount and acts as a first polarization region that first-polarizes the transmitted light to produce a first polarized light;
a second light-transmitting region that is formed in the light-transmitting substrate on a second side of the light-blocking region opposite to the first phase shift region, acts as a second phase shift region that phase-shifts a transmitted light by a second amount different from the first amount, and acts as another first polarization region that first-polarizes the transmitted light to produce a further first polarized light; and
a third light-transmitting region that is formed in the light-transmitting substrate, contacts the first and second light-transmitting regions to form a boundary at an end of the light-blocking region, and acts as another first phase shift region and a second polarization region that second-polarizes the transmitted light to produce a second polarized light.

9. The PSM of claim 8, wherein the first polarization is transverse electric (TE) polarization and the second polarization is transverse magnetic (TM) polarization.

10. The PSM of claim 9, wherein the first light-transmitting region comprises a first grating extending in a predetermined direction and having a first depth to produce the first polarization, the second light-transmitting region comprises a second grating having a second depth greater than the first depth that results in a phase difference between the light transmitted through the first light-transmitting region and the light transmitted through the second light-transmitting region, the second grating extending in the same direction as the first grating, and the third light-transmitting region comprises a third grating having a depth equal to the first depth and extending in a direction perpendicular to the direction of the second grating to obtain the second polarization.

11. A phase shift mask (PSM) comprising:
a light-transmitting substrate;
a light-blocking region formed on the light-transmitting substrate;
a first phase shift region that is formed in the light-transmitting substrate and transmits light with a first phase;
a second phase shift region that is formed in the light-transmitting substrate, contacts the first phase shift region to form a boundary, and transmits light with a second phase different from the first phase;
a first polarization part formed in the first phase shift region adjacent to the boundary to first-polarize the transmitted light; and
a second polarization part formed in the second phase shift region adjacent to the boundary to second-polarize the transmitted light.

12. The PSM of claim 11, wherein the first and second polarization parts extend over the entire first phase shift region and the second phase shift region.

13. The PSM of claim 11, wherein the first polarization is transverse electric (TE) polarization and the second polarization is transverse magnetic (TM) polarization.

14. The PSM of claim 13, wherein the first polarization part comprises a first grating that extends in one direction and the second polarization part comprises a second grating that extends in a direction perpendicular to the direction in which the first grating extends.

15. The PSM of claim 11, wherein the first phase shift region and the second phase shift region are formed by etching the light-transmitting substrate at different depths so that the first and second phase shift regions transmit light with different phases.

16. The PSM of claim 11, wherein the first phase shift region is formed without etching the light-transmitting substrate and the second phase shift region is formed by etching the light-transmitting substrate to a predetermined depth so that the first and second phase shift regions transmit light with a phase difference.

17. The PSM of claim 11, wherein the first phase shift region having the first polarization part comprises a first grating that extends in a predetermined direction and is formed to a first depth to obtain TE polarization, and the second phase shift region having the second polarization part comprises a second grating that extends perpendicularly to the first grating to obtain TM polarization and is formed to a second depth greater than the first depth to obtain a phase difference with respect to the first phase shift region.

18. The PSM of claim 11, wherein the first and second phase shift regions transmit light with an optical phase difference of 180°.
